(19) United States
(12) Patent Application Publication
(10) Pub. No.: US 2008/0145517 A1
(43) Pub. Date: Jun. 19, 2008

(54) METHOD FOR MANUFACTURING PLASMA DISPLAY PANEL, AND APPARATUS FOR INSPECTING PLASMA DISPLAY PANEL

(76) Inventors: Hideaki SASAZAWA, Yokohama (JP); Mineo Nomoto, Fujisawa (JP); Kouji Kashiwagi, Yugawara (JP); Shigeru Saitou, Kobayashi (JP); Tomohiko Murase, Miyazaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/834,036

(22) Filed: Aug. 6, 2007

(30) Foreign Application Priority Data
Dec. 19, 2006 (JP) 2006-341665
Jul. 17, 2007 (JP) 2007-185787

(51) Int. Cl. C23C 14/54

(52) U.S. Cl. 427/10; 427/9

(57) ABSTRACT

A method for manufacturing a plasma display comprises: a phosphor painting process for painting phosphor layer in ribs formed on a back plate; and a phosphor inspection process that includes the steps of: irradiating the phosphor layer with ultraviolet light; preparing an imaging system so that the imaging system images the emitted light beam to acquire information on brightness; comparing the brightness information with correlation between a shape model of the phosphor layer and brightness signal information that have been obtained in advance; and obtaining a painted state of the phosphor layer painted in the ribs; and a process for feeding back the applied state of the phosphor layer, which has been obtained in the phosphor inspection process, to the phosphor painting process so that the manufacturing equipment is controlled in the phosphor painting process.

### BACKGROUND OF THE INVENTION

1. Field of the Invention

The present invention relates to a method for manufacturing a plasma display panel, and an apparatus for inspecting a plasma display panel. In particular, the present invention relates to a painted amount/painted position control in a phosphor painting process at the time of manufacturing a back plate of a plasma display panel, and to an effective technology for judging the result of the application with in high accuracy.

2. Description of the Related Art

When a plasma display panel (hereinafter referred to as “PDP”) is manufactured, a front plate on which transparent electrodes are located, and a back plate to which phosphors are painted, is separately made. Then, the front and back plates are joined together to form one panel. Usually, phosphors used for R (red), G (green), B (blue) are repeatedly and successively painted on the striped ribs of a back plate of a PDP. However, if each phosphor is not uniformly painted in ribs, for example, the following malfunctions occur: the brightness and hue of displaying become nonuniform, which is unevenness of color; a phosphor of a certain color extends over an adjacent phosphor region, which causes color mixture; and lack of paint creates a dark spot that cannot emit light.

In order to prevent a back plate, which may have the above-described malfunctions in a state in which phosphors are painted, from being joined together with a front plate, it is necessary to separately inspect the back plate without fail. In addition, if a malfunction occurs in the painted state, the malfunction in a manufacturing process should be immediately corrected to prevent a defective product from being manufactured. In order to achieve this, it is also necessary to separately inspect the back plate without fail. This inspection is usually performed by irradiating, with ultraviolet rays, a back plate of a plasma display panel to which each phosphor is painted so that the ultraviolet rays cause a phosphor layer to be excited and to emit light beams, and then by receiving the light beams.

For example, simple and easy methods for inspecting whether or not a phosphor layer is correctly painted and formed in ribs are disclosed in, for example, JP-A-Hei-11-16498 (Patent Document 1) and JP-A-2001-15030 (Patent Document 2). These inspection methods will be simply described with reference to FIG. 20 as below.

An ultraviolet source 142 irradiates, with ultraviolet light 143, a back plate 141 on which the formation of phosphors is completed. The phosphors are excited by the ultraviolet light. As a result, the phosphors emit light beams. The emitted light beams 144 are detected by a camera 145. A processing system 146 acquires a detected signal to inspect a defective state.

This is an inspection method for inspecting the whole surface of the back plate by consecutively scanning the back plate 141 or the ultraviolet source 142 and the camera 145. In Patent Document 2, other than the detection in a direction perpendicular to the substrate 141 by the detection camera 145, a method for detecting a defect at an angle of 45° or less is also disclosed.

In addition, in Patent Document 1, a method which includes a mechanism for exhausting ozone caused by ultraviolet light is also disclosed in the above document.

### SUMMARY OF THE INVENTION

In Patent Documents 1 and 2, a phosphor layer formed in ribs is excited by ultraviolet light. This causes the phosphor layer to excite/emit light beams. Then, the emitted light beams are detected above a substrate or from an oblique direction at an angle of 45° or less. In these methods, an image signal detected by a camera is compared with a reference value to make a judgment as to whether or not a defect (for example, color mixture of phosphors, unpainted phosphor, a fluorescent light failure caused by foreign particles, or uneven brightness) exists. Therefore, a change in shape of the phosphor layer in the ribs is not correctly detected, which occurs in a painting process.

For the above reason, it is not possible to detect a change in state of phosphor paint, which is caused by fluctuations in process that are not judged to be a defect. Accordingly, the control of feedback to the manufacturing process including the painting process cannot be carried out. This is a problem to be solved.

The present invention has been made to solve the above problem. According to one aspect of the present invention, there is provided a plasma-display manufacturing method including a phosphor painting process for painting phosphors in ribs formed on a back plate, said plasma-display manufacturing method comprising:

a step of irradiating the phosphor layer with ultraviolet light to cause the phosphor layer to emit a light beam, the phosphors being painted in the ribs;

a step of preparing an imaging system so that the imaging system images the emitted light beams to acquire an image;

a step of separating the acquired image into RGB planes;

a step of inspecting a defect of the phosphors painted in the ribs based on each of the RGB planes;

a phosphor inspection step of obtaining information on a defect of the phosphor layer; and

a step of feeding back the information obtained in the phosphor inspection step to the phosphor painting process so that manufacturing equipment is controlled in the phosphor paint process.

According to another aspect of the present invention, there is provided a plasma-display manufacturing method including a phosphor painting process for painting phosphors in ribs formed on a back plate, the plasma-display manufacturing method comprising:

a step of irradiating the phosphor layer with ultraviolet light to cause the phosphor layer to emit a light beam, the phosphors being painted in the ribs;

a step of preparing an imaging system so that the imaging system images the emitted light beams in a certain direction to acquire an image;

a step of separating the acquired image into RGB planes;

a step of obtaining a differential area between the RGB planes;

a step of inspecting a defect of the phosphors painted in the ribs based on the obtained differential area;

a phosphor inspection step of obtaining information on a defect of the phosphor layer, the information including the position, shape, and size of the defect; and

a step of feeding back the information obtained in the phosphor inspection step to the phosphor painting process so that manufacturing equipment is controlled in the phosphor painting process.

According to another aspect of the present invention, there is provided a plasma-display manufacturing method including a phosphor painting process for painting phosphors in ribs formed on a back plate, the plasma-display manufacturing method comprising:

a step of irradiating the phosphor layer with ultraviolet light to cause the phosphor layer to emit a light beam, the phosphors being painted in the ribs;

a step of preparing an imaging system so that the imaging system images the emitted light beams in a plurality of directions to acquire a plurality of images;

a step of separating each of the acquired images into RGB planes;

a step of comparing the RGB planes with each other and inspecting a defect mode of the phosphors painted in the ribs;

a phosphor inspection step of obtaining information on a defect of the phosphor layer, the information including the defect mode; and

a step of feeding back the information obtained in the phosphor inspection step to the phosphor painting process so that manufacturing equipment is controlled in the phosphor painting process.

According to another aspect of the present invention, there is provided a plasma-display manufacturing method including a phosphor painting process for painting phosphors in ribs formed on a back plate, the plasma-display manufacturing method comprising:

a step of irradiating the phosphor layer with ultraviolet light to cause the phosphor layer to emit a light beam, the phosphors being painted in the ribs;

a step of preparing an imaging system so that the imaging system images the emitted light beams to acquire information on brightness;

a step of comparing the brightness information with correlation between a shape model of the phosphor layer and brightness signal information that have been obtained in advance;

a phosphor inspection step of obtaining a painted state of the phosphor layer painted in the ribs; and

a step of feeding back the information obtained in the phosphor inspection step to the phosphor painting process so that manufacturing equipment is controlled in the phosphor painting process.

According to another aspect of the present invention, there is provided a plasma-display inspection apparatus for inspecting a phosphor layer that is formed on a back plate of a plasma display, the plasma-display inspection apparatus comprising: ultraviolet-light irradiation optical system for exciting and irradiating the phosphor layer with ultraviolet light; an imaging unit for imaging light beams emitted from the phosphor layer that has been excited and irradiated by the ultraviolet-light irradiation optical system; an image processing unit for separating the image generated by the imaging unit into RGB planes to extract the feature (for example, brightness profile) of an emission state; and shape/in-plane distribution recognition unit for calculating a painted state (including shape and profile) of the phosphor layer from the extracted feature, and from data of the correlation between a phosphor-layer shape model and the feature of the emission state.

In addition, the image processing unit separates, into RGB planes, an image that is generated from at least one direction, and then determines each difference area between the RGB planes so that a position, a shape, and the area (size), of a defect are extracted.

Moreover, said shape/in-plane distribution recognition unit separates, into RGB planes, each of images that are acquired by imaging from at least two directions, and then compares each of the RGB planes of the image acquired by imaging from one direction with each of the RGB planes of the image acquired by imaging from the other direction to judge a defect mode.

A system for manufacturing a plasma display comprises:

a state judgment unit for, from phosphor-layer shape distribution data calculated by the shape/in-plane distribution recognition unit, judging fluctuations in a phosphor painting process; and

a control unit for controlling parameters of manufacturing equipment in the phosphor painting process on the basis of the result of the judgment.

If the manufacturing method according to the present invention is used, it is possible to correctly recognize (keep track of) a state in which phosphors are painted, and a shape of a phosphor layer, in a phosphor formation process included in a PDP manufacturing process, and to quickly feed back them to the manufacturing process. This produces extremely large effects of improving yields, improving the processes, and preventing a failure from occurring.

Moreover, if the inspection apparatus according to the present invention is used, it is possible to detect a minute defect, in particular, a slight change in phosphor shape, which is not judged to be a defect in the past, so that process fluctuations can be minutely recognized (kept track of).

### BRIEF DESCRIPTION OF THE DRAWINGS

FIG. 1 is a diagram illustrating a configuration of an inspection apparatus according to this embodiment;

FIGS. 2A, 2B are a diagram and a table, respectively, for illustrating the layout of a detection system and resolution specifications according to this embodiment;

FIG. 3 is a flowchart illustrating the process flow of an image processing unit according to this embodiment;

FIG. 4 is a diagram illustrating processing performed by the image processing unit according to this embodiment;

FIG. 5 is a diagram illustrating defect-mode judgment processing according to this embodiment;

FIG. 6 is a diagram illustrating cross-sectional properties of each defect mode;

FIG. 7 is a diagram illustrating the correspondence between a shape of a phosphor layer and a detected brightness profile;

FIG. 8 is a diagram illustrating an example of a defect distribution map;

FIG. 9 is a diagram illustrating an example of a misalignment amount map;

FIG. 10 is a flowchart illustrating the control of a paint process based on a manufacturing method according to this embodiment;

FIG. 11 is a table illustrating how defect modes correspond to probable causes in a manufacturing process;

FIG. 12 is a perspective view illustrating an inspection apparatus according to this embodiment;

FIG. 13 is a flowchart illustrating a PDP manufacturing process;

FIG. 14 is a diagram illustrating a phosphor painting process based on a screen printing method;

FIG. 15 is a perspective view illustrating a phosphor painting apparatus based on the screen printing method;

FIG. 16 is a perspective view illustrating a phosphor painting apparatus based on a dispenser method;

FIG. 17 is a diagram illustrating a configuration of an image processing unit according to another embodiment;

FIG. 18 is a diagram illustrating another embodiment of defect-mode judgment processing;

FIG. 19 is a diagram illustrating a PDP structure; and

FIG. 20 is a diagram illustrating a configuration of a conventional inspection apparatus.

### DETAILED DESCRIPTION OF THE PREFERRED EMBODIMENTS

Best modes for carrying out the present invention will be described as below.

### First Embodiment

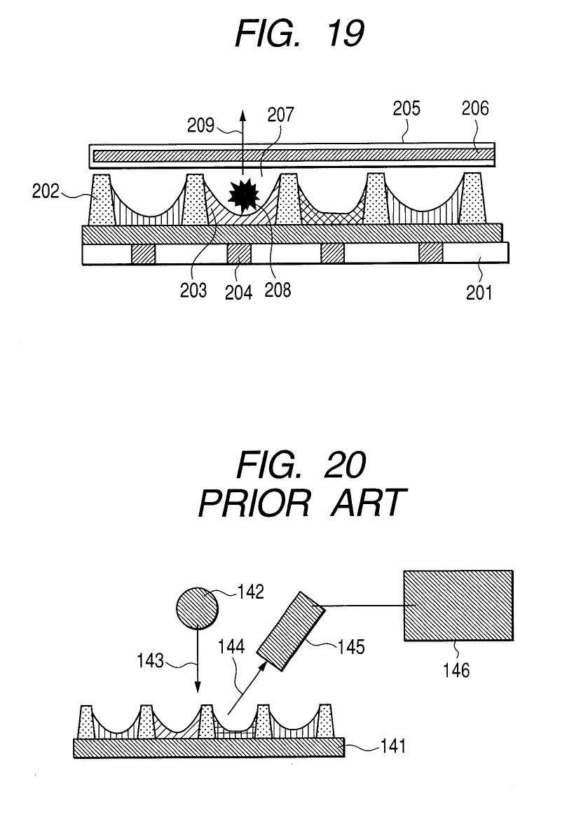

A method for manufacturing a PDP and an apparatus for inspecting a PDP according to a first embodiment of the present invention will be described with reference to drawings as below. First of all, a simple configuration of a target PDP according to a first embodiment will be described with reference to FIG. 19. Stripe-shaped rib walls 202 are formed on back glass 201. A phosphor layer 203 which emits three color (RGB) beams is filled between the rib walls 202. Front plate glass 205 is located on the upper part of the ribs; and a gap between the front plate glass 205 and the back plate is filled with gas. Plasma discharge 208 is performed between a transparent electrode 206 of the front plate and an address electrode 204 in the back plate so that ultraviolet rays are emitted, the address electrode 204 being orthogonal to the transparent electrode 206. The ultraviolet rays cause a phosphor in each pixel to be excited, and to emit light, so that a light emission pixel 209 creates video.

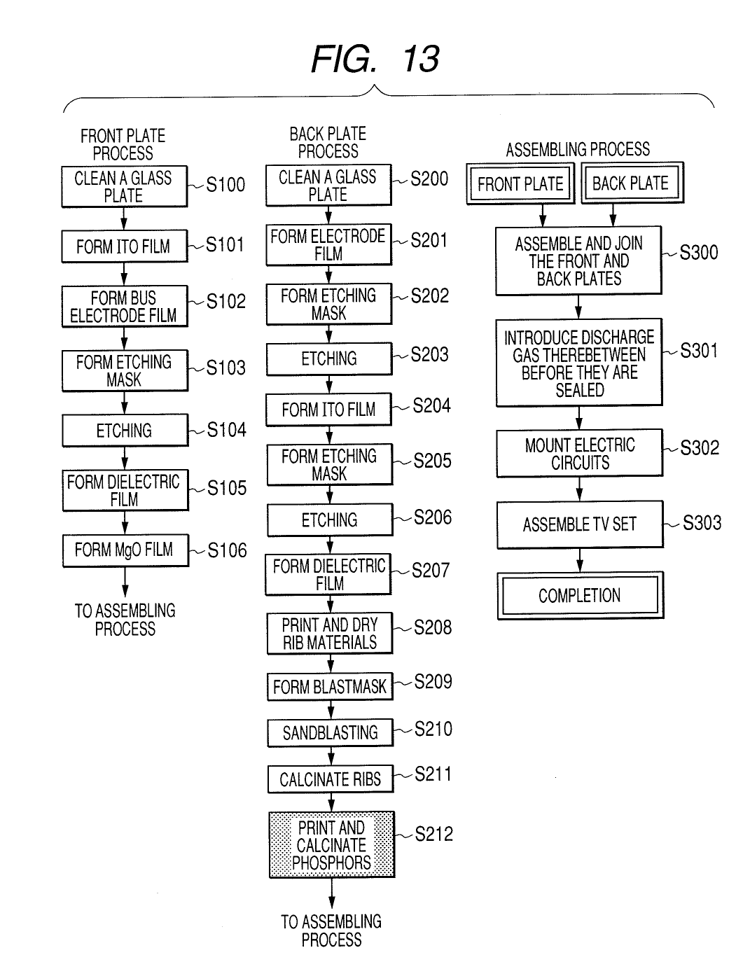

Next, a manufacturing process of PDP according to the first embodiment will be described with reference to FIG. 13. First of all, in a front plate process, a glass substrate is cleaned (S100), and a transparent ITO electrode is formed by sputtering (S101). Next, a bus electrode is formed by, for example, photolithography (photomasking and etching) (S102). Then, dielectric film is painted and calcinated (baked) (S103 to S105), MgO film, which is a protective layer, is deposited to achieve film formation (S106).

A back plate process also starts with glass substrate cleaning in like manner (S200). After the address electrode is formed by photolithography, or the like (S201 to S206), dielectric film is formed (S207). After that, in contrast to the front plate process, a rib material is printed and dried to form a rib layer (S208). Then, mask for sandblast is formed (S209). The ribs are formed by sandblasting (S210), and are then calcinated to complete the formation of the rib walls (S211). The rib walls are filled with phosphor paste by printing, or the like. The rib walls are then calcinated to cause the phosphors to adhere to the rib walls (S212).

Lastly, on the completion of the formation of the front and back plates, both of them are assembled and joined together (S300). Then, vacuuming is performed, and discharge gas is introduced therebetween before they are sealed (S301). Then, a driving circuit is mounted to the panel (S302), which is assembled as a TV set (S303).

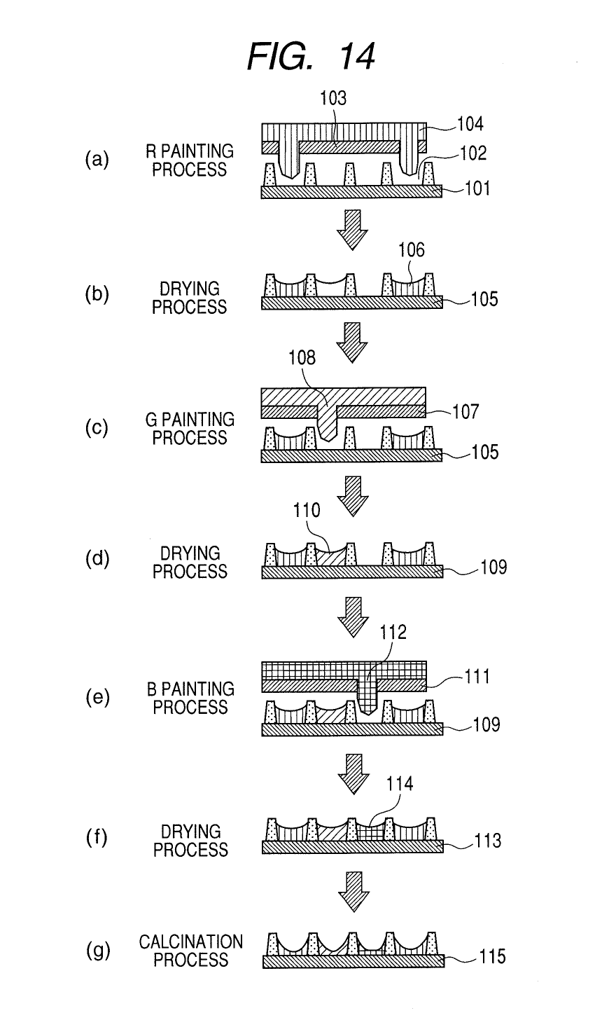

Here, a phosphor printing (painting)/calcination process S212, which in particular relates to this embodiment, will be described in detail with reference to FIG. 14. FIGS. 14A to 14G are diagrams illustrating an example of a phosphor paint process by a printing method.

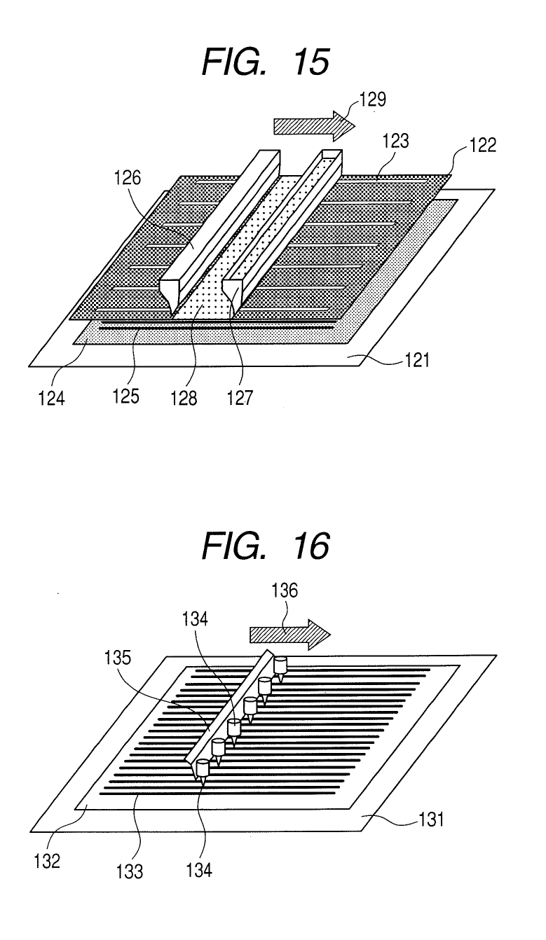

As shown in FIG. 14A, after the ribs are formed, the back plate 101 is transferred to a painting apparatus (FIG. 15) for painting a first phosphor (hereinafter referred to as “R”), and is then aligned to an R printing mask 103. The mask 103 is provided with a pattern so that specified ribs 102 are filled with R phosphor paste 104. The back plate 101 is filled with the R phosphor paste 104 by a screen printing method. After the printing on whole surface of the back plate is completed, a solvent component included in the filled phosphor 106 volatilizes by a dry process, and the R-phosphor-filled back plate 105 becomes stable as shown in FIG. 14B.

Next, as shown in FIG. 14C, in a painting process of a second phosphor (hereinafter referred to as “G”), a G printing mask 107 is aligned to the R-phosphor-filled back plate 105 in like manner. Then, screen printing is performed so that specified ribs are filled with G phosphor paste 108. After the printing on whole surface of the back plate is completed, a solvent component included in the filled phosphor 110 volatilizes by a dry process as shown in FIG. 14D. As a result, a G-phosphor-filled back plate 109 becomes stable.

As shown in FIG. 14E, in a paint process of a third phosphor (hereinafter referred to as “B”), specified ribs of the G-phosphor-filled back plate 109 are filled with B phosphor paste 112 using a B printing mask 111 in like manner. After the printing on the whole surface of the substrate is completed, a solvent component included in the filled phosphor 114 volatilizes by a dry process, and a B-phosphor-filled back plate 113 becomes stable as shown in FIG. 14F.

Lastly, in a calcination process, the back plate 113 to which all of the phosphors have been printed is calcinated. As a result, the formation of a back plate 115 provided with the phosphors is completed.

The principles of a printer used for such a phosphor printing/calcination process S212 will be described with reference to FIG. 15. A back plate 124 is placed on a base 121 of an apparatus. After the back plate 124 is aligned, the back plate is secured to the base 121. A mask 122 corresponding to a kind of a substrate to be manufactured and a kind of a phosphor to be manufactured are put on the back plate 124 to perform alignment. An printing head 127 scans the mask 122 at constant speed from one end of the mask 122 up to the other end in a direction indicated with an arrow 129 with a fixed quantity of phosphor paste 128 being linearly printed to the mask 122. A squeegee 126 is scanned from the back of the printing head 127. The phosphor paste 128 on the mask is filled into the specified ribs 125 of the back plate 124 from an opening of the mask pattern 123.

In addition, the principles of a painting apparatus using a dispenser method, which is another applying method, will be described with reference to FIG. 16. A back plate 132 is placed on a base 131 of the apparatus. After the back plate 132 is aligned, the back plate is fixed to the base 131. By use of a painting head 135 equipped with a plurality of dispensers 134 corresponding to a kind of a substrate to be manufactured, the back plate is scanned from one end of the back plate at constant speed in a direction indicated with an arrow 136. At this time, a fixed quantity of phosphor paste is filled into specified ribs 133 of the back plate 132 from each of the dispensers 134. As clearly understood from the configuration of the apparatus, in the case of this method, it is also possible to fill all kinds (all colors) of the phosphor paste at a time by changing a kind of the phosphor paste to be stored in each of the dispensers.

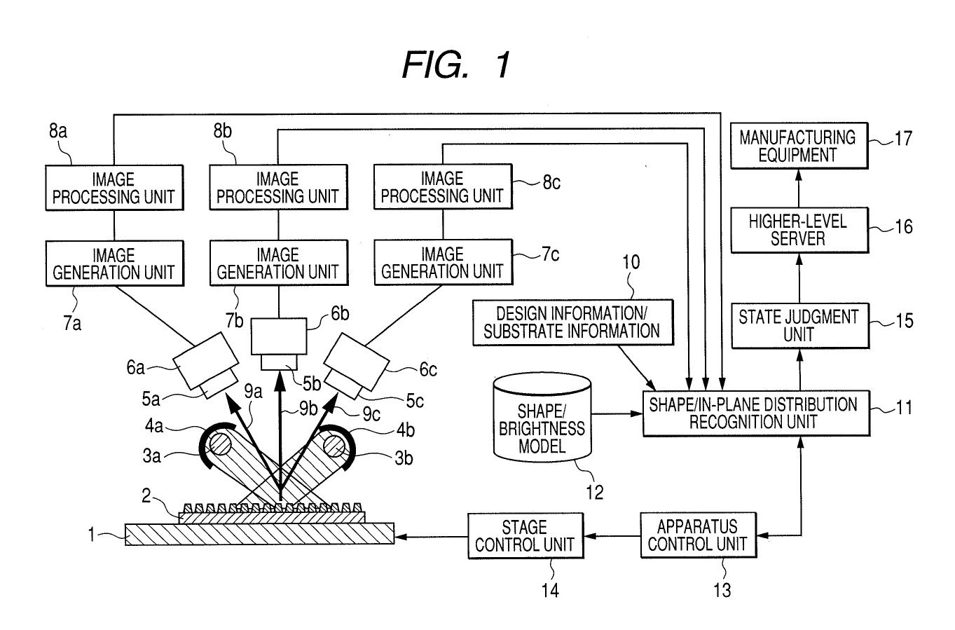

A configuration of an inspection apparatus for inspecting a state of a phosphor layer, which is formed in ribs in this manner, will be described with reference to FIG. 1. A back plate 2, which is a target to be inspected, is placed on a sample stage 1 for holding the back plate 2. Stage control unit 14 controls the sample stage 1 so that the sample stage 1 is kept located at an arbitrary position. It should be noted that reference numeral 13 denotes an apparatus control unit for controlling the entire inspection apparatus. The inspection apparatus control unit 13 is configured to connect the stage control unit 14 and a shape/in-plane distribution recognition unit 11. Ultraviolet light sources 3a, 3b are located above the target back plate 2, and reflecting plates 4a, 4b are used respectively to irradiate the substrate with ultraviolet light beams that face each other. The phosphor layer formed in the ribs of the back plate 2 is excited by the ultraviolet light beams. This causes the emission of fluorescent light.

The emitted fluorescent light beams 9a, 9b, 9c are condensed by detection lenses 5a, 5b, 5c, each of which is located at a different position (left-inclined position, substantially vertical position, right-inclined position) at which the angle between the lens in question and the back plate 2 differs from the angle between each of the other lenses and the back plate 2. The detection lens 5a and a photodetector 6a can detect the fluorescent light beam 9a from the left rib wall. The detection lens 5c and a photodetector 6c can detect the fluorescent light beam 9c from the right rib wall. The condensed fluorescent light beams 9a, 9b, 9c are then detected by photodetectors 6a, 6b, 6c respectively. Image generation units 7a, 7b, 7c generate two-dimensional images from the detected signals, and then transmit the two-dimensional images to image processing units 8a, 8b, 8c respectively. The image processing units 8a, 8b, 8c calculate the position, shape, area (size) and the like of a defect, which are the features of the phosphor layer, from the two-dimensional images in imaging processing described below. The result of the calculation is then transmitted to a shape/in-plane distribution recognition unit 11. By the method described below, the shape/in-plane distribution recognition unit 11 calculates the shape of the phosphor layer of the detected substrate and data on the panel in-plane distribution of each shape parameter by use of design information/substrate information 10 on the height of the ribs, the shape of the phosphor layer and the like, the panel in-plane distribution of each shape parameter, the type of the substrate (back plate), and the like and by use of database 12 on correlation between a shape of the phosphor layer and light emission brightness model (database 12 on correlation between shape model and brightness profile). A state judgment unit 15 judges a state including a defect position, a defect mode, and process fluctuations on the basis of the calculated data. Then, the state judgment unit 15 judges the state such as defect position, defect mode, and process fluctuation and uploads the state information to a higher-level server 16. Incidentally, the higher-level server 16 manages the manufacturing process in an integrated manner, and gives an instruction to manufacturing equipment 17 (phosphor painting apparatus comprises phosphor printing/calcination apparatus, etc.) if necessary.

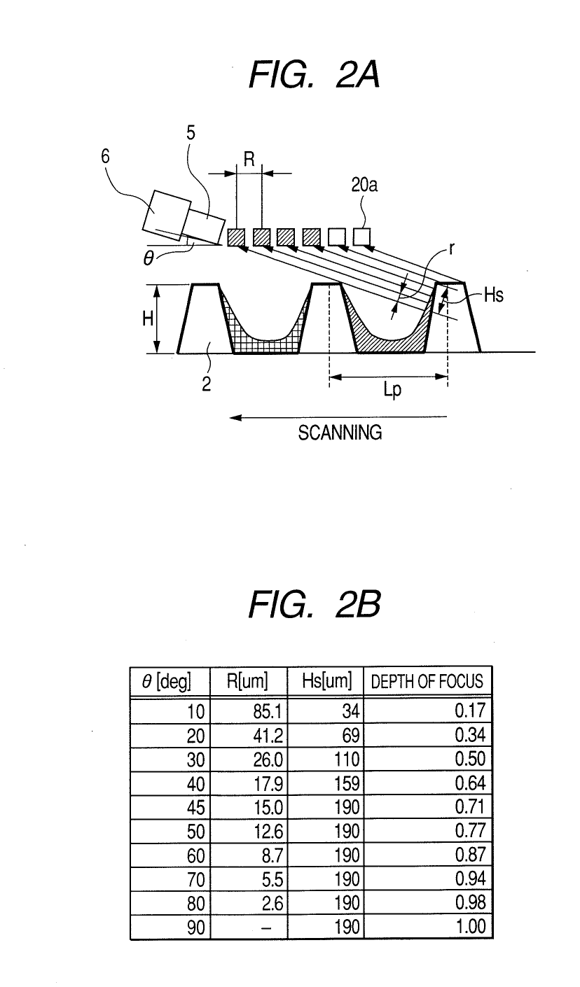

Next, each configuration will be described in detail. FIG. 2A is a diagram illustrating a relation between the inclination angles θ of the detection lens (the objective lens) 5 and the detection resolution R [μm] etc. of the photodetector 6 that are provided with different angles as shown in FIG. 1. To explain easily here, only one detection lens and photodetector were described. The photodetector 6 is composed of a linear sensor arranged, for example, in a vertical direction of space and detects pixels 20a one by one by scanning the substrate (the back plate) 2 to the horizontal direction of space to obtain two-dimension image.

In the case of a 50-inch PDP panel, on the assumption that a horizontal to vertical ratio of 16:9, which is used by high-definition television screens, is adopted, a rib interval of the back plate, the number of lateral pixels of which is 1920 (full high-definition television), is about 190 μm (Lp=190 μm as shown in FIG. 2) because three colors (RGB) correspond to one pixel. In addition, on the assumption that a rib wall is vertical for the sake of simplification, if the panel is viewed from an oblique direction θ, a visible length of the rib sidewall portion Hs is Hs=Lp×tan θ (however, Hs doesn't exceed height H of the rib). Accordingly, if the maximum angle at which humans can view TV is in general 10°, a visible length of the rib sidewall portion Hs becomes equivalent to 34 μm and a phosphor material of 34 μm in the rib sidewall will be viewed as the result. Under such a condition that the maximum angle is in general 10°, it is necessary to detect photodetector 6 by imaging with the resolution of about at least ½ of 34 μm in the observational area because it becomes a minimum defect size that the defect that can be acknowledged should detect from the rib sidewall. Accordingly, in the present embodiment, the minimum detection resolution r that the photodetector 6 can be detected by imaging on the rib sidewall is kept at about 15 μm. In order to satisfy the minimum detection resolution r that can detect the minimum defect that can be the acknowledgment on the rib sidewall in the inclination angle θ, the detection resolution R that detects by the image sampling in the direction of the scanning with the photodetector 6, becomes R=r/tan θ. In a case of the inclination angle is, for example, 60°, the photodetector 6 should detect by performing the image sampling in the direction of the scanning with an interval of about the R=about 8.7 μm or less. In a case of the inclination angle is, for example, 45°, the photodetector 6 should detect by performing the image sampling in the direction of the scanning with an interval of the R=about 15 μm or less. In a case of the inclination angle is, for example, 20°, the photodetector 6 should detect by performing the image sampling in the direction of the scanning with an interval of the R=about 41.2 μm or less. FIG. 2B shows these conditions in the table. However, when the inclination angle θ approaches vertical direction being 90°, since the detection resolution R that the photodetector 6 can image becomes about 0, the photodetector 6 cannot image a minimum defect on the rib sidewall. The explanation is omitted for θ>90° because it becomes symmetric in case of θ<90°.

By the way, the limit of the height Hs of the rib wall that the photodetector 6 can image is decided by the aspect ratio of the rib height H and the rib pitch Lp. In general, it was assumed that Hs is also 190 μm at the maximum because rib pitch Lp and height H of the rib are same levels (the aspect ratio being 1.0) according to the restriction in the rib manufacturing and the thickness etc. of the phosphor layer. That is, when the inclination angle θ becomes 450 or more, since the height Hs of the rib wall that the photodetector 6 can image, becomes same 190 μm as rib pitch Lp, the photodetector 6 can image an entire area of the phosphor layer in the rib wall as the result. When the inclination angle θ becomes 450 for example, the height Hs of the rib wall that the photodetector 6 can image will be limited to about 69 μm.

Moreover, if the focus depth of the detection lens 5 is assumed as “1” when the inclination angle θ is 90°, the effective focus depth of the detection lens 5 at the time of inclination detection decreases in the proportion of sin θ in comparison with vertical detection. As a result, the focus depth becomes shallow becoming small of the inclination angle θ as shown in FIG. 2B, and there is a necessity for using the detection lens 5 with deep focus depth.

As explained above, in the design of actual detection systems 5a˜5c, 6a˜6c, it may be performed under the condition of showing in FIG. 2B. And, the detection systems 5a, 5c; 6a, 6c mutually opposed are provided and if the inclination angle θ makes within the range of about 50°-60°, the focus depth of the detection lens can be secured about 0.8 times or more, and an enough scanning speed for scanning the substrate can be obtained with the detection resolution (image sampling interval) about 12.6 μm-8.7 μm, and in addition, since the height Hs of the rib wall that can be imaged becomes same 190 μm as the rib pitch Lp, the photodetector can image an entire area of the phosphor layer in the rib wall as the result.

In case of the condition the inclination angle θ at low angle or more, since scanning direction detection resolution R may be large, the substrate can be scanned at high speed. However, the detection system provided the detection lens with beforehand very long focus depth or a mechanism that keeps constantly a distance between the substrate and the detection lens is needed. Oppositely, in case of the inclination angle θ at high angle, there is a necessity for reducing the scanning direction detection resolution R, and if the detection rate of the photodetector is invariable, there is a necessity for slowing down the detection speed (the scanning speed).

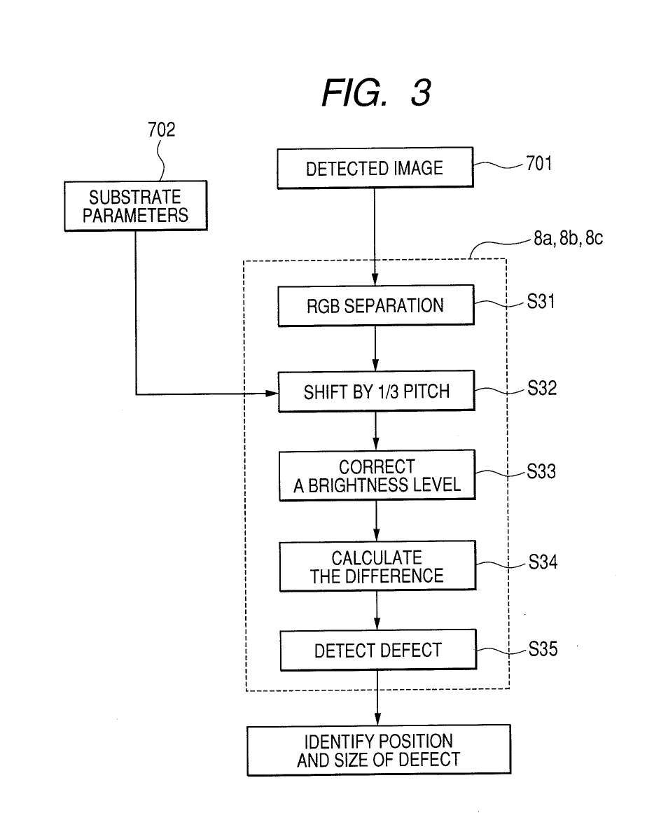

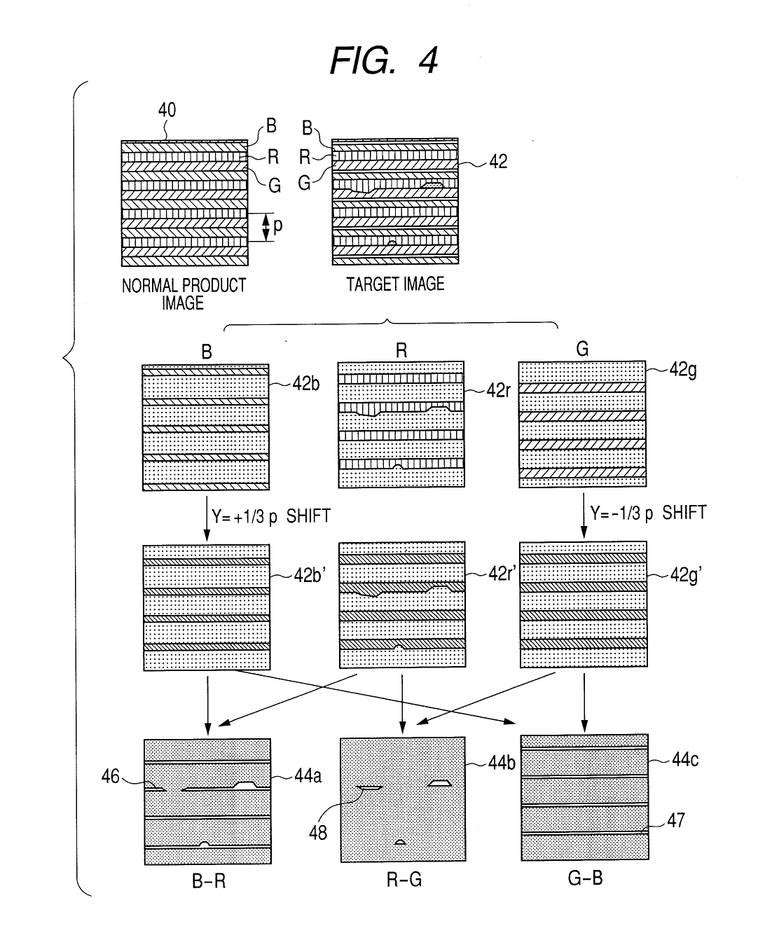

Next, an example of processing in the image processing units 8a, 8b, 8c will be described in detail with reference to FIGS. 3, 4. FIG. 3 is a flowchart showing a process performed in each of the image processing units 8a, 8b, 8c. FIG. 4 is a diagram showing the process performed in the image processing units 8a, 8b, 8c. Incidentally, irrespective of the detected angles θ, each method for carrying out the processing is the same. Accordingly, the processing will be described by use of an image detected by one detector. In this example, each of the photodetectors 6a, 6b, 6c is a color detector that is capable of detecting the brightness and hue of light.

Processing of continuous defect detection according to the first embodiment will be described as below. First of all, a target image 42 to be subjected to the processing is taken out from an obtained detected image 701 by the image processing units 8a, 8b, 8c. For the sake of description, an example in which continuous position misalignment defects and a plurality of isolated defects exist is shown. An example in which continuous position misalignment defects have occurred at the time of applying B phosphors is shown (in comparison with a normal product image 40, all of the B phosphors deviate in an R phosphor direction).

The target image 42 which has been taken out from the detected image is separated into RGB planes of a color image by each of the imaging processing units (S31). A direction in which the RGB planes are arrayed, and the panel pixel pitch P, are acquired from substrate design information (substrate parameters) 702 by each of the image processing units. Then, according to the RGB arrayed direction, a B-plane image 42b is shifted by +⅓ P in a Y direction, and a G-plane image 42g is shifted by −⅓ P in the Y direction (S32). Next, “Gain adjustment” is performed on the image by each of the image processing units so that the brightness values in the planes coincide with one another. Then, images 42b′, 42r′, 42g′ after the brightness adjustment are acquired (S33). Next, the difference between the images is calculated by each of the image processing units to output a difference image 44a corresponding to (B plane)−(R plane), a difference image 44b corresponding to (R plane)−(G plane), and a difference image 44c corresponding to (G plane)−(B plane) (S34). As a result, each of the image processing units detects that a position misalignment defect occurs in a linear defect 46 included in the difference image 44a, and in a linear defect 47 included in the difference image 44c (S35). Because both of the difference images includes the B plane, it is judged that a position misalignment defect has occurs in the B phosphor. Moreover, judging from the difference area 48 included in the difference image 44b, it is also understood that an isolated defect has occurred.

Thus, by separating at least an image obtained from one direction (a specified direction) into the RGB planes to determine each difference area between the RGB planes, each of the image processing units can detect a change in phosphor shape, which conventionally has not been judged to be a defect, and identify a position, a shape, and the area (size), of the defect.

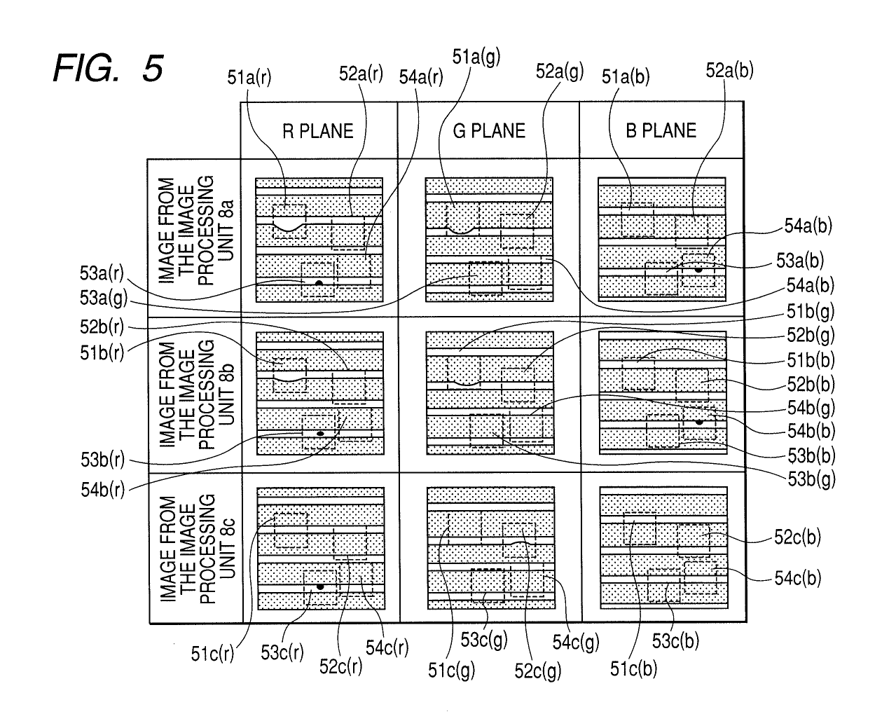

Next, an example of defect mode judgment performed in the shape/in-plane distribution recognition unit 11 will be described in detail with reference to FIGS. 5, 6. Because the position, the shape, and the size, of the defect are identified by the processing of the image processing units 8a, 8b, 8c, the shape/in-plane distribution recognition unit 11 extract an area which includes the defect from an image of each of the image processing units 8a, 8b, 8c and judges a defect mode from a defect state of each plane.

To be more specific, in the case of a defective area 51a (r), which has been detected in the R plane included in an image from the image processing unit 8a, the shape/in-plane distribution recognition unit 11 compares an area 51a (r) that has been detected in the plane R in an image of the left rib wall from the image processing unit 8a with areas 51a (g), 51a (b) in the other planes G, B from the image processing unit 8a and areas 51b (r), 51b (g), 51b (b) in the planes R, G, B in an image from the top of the ribs from the image processing unit 8b and areas 51c (r), 51c (g), 51c (b) in the planes R, G, B in an image of the right rib wall from the image processing unit 8c, all of which correspond to the same position on the substrate. Based on the comparison, it is judged that the areas 51c (r), 51c (g), 51c (b) in the images from the image processing unit 8c do not include a defect, and that the areas 51a (b), 51b (b) in the images from the B plane also do not include a defect. In addition, the size of the defect in the area 51a (r) is larger than that of the defect in the area 51b (r). Similarly, the size of the defect in the area 51a (g) is larger than the size of the defect in the area 51b (g). Therefore, the defect in the area 51a (r) is judged to have a shape as shown in the defect 51 in FIG. 6; and the defect is also judged to be included in a defect mode in which the R phosphor 62 extends over the surface of the rib wall of the G phosphor 61.

Similarly, in the case of the defect in the area 52c (g) detected based on the image from the image processing unit 8c, because there is no defect in the other areas, the shape/in-plane distribution recognition unit 11 judges the defect in the area 52c (g) to be a phosphor missing defect on the G rib wall 63. This phosphor missing defect has a shape of the defect 52 shown in FIG. 6.

Next, in the case of the defect in the area 53a (r), because both of the areas 53b (r), 53c (r) include a defect having nearly the same size, and because the other G, B planes do not include a defect, the shape/in-plane distribution recognition unit 11 judges the defect in the area 53a (r) to be a defect that has a shape of the defect 53 shown in FIG. 6, and that is caused by a foreign particle 65 in the R rib 64.

Moreover, in the case of the defect in the area 54a (r), because all of the areas 54b (r), 54a (b), 54b (b) include a defect having nearly the same size, and because the G plane and an image from the image processing unit 8c do not include a defect, the shape/in-plane distribution recognition unit 11 judges the defect in the area 54a (r) to be a color mixture defect that has a shape of the defect 54 shown in FIG. 6, and that is caused by the R phosphor 67 adhered to a side wall in the B rib 66.

Thus, the judgment of a defect mode makes it possible to correctly recognize a process state in the painting process of the phosphor layer.

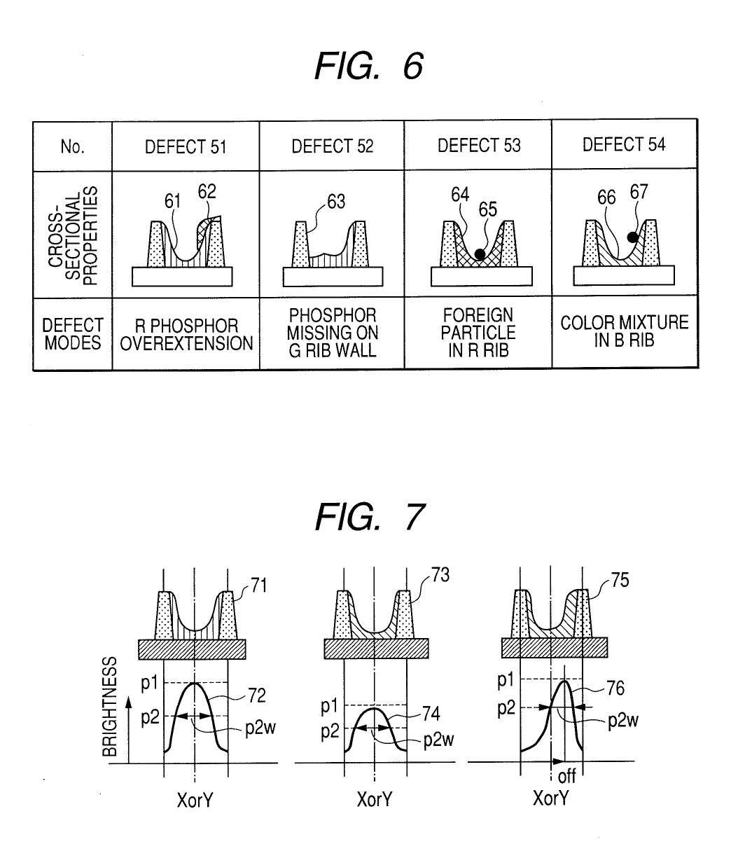

Next, an example of phosphor-layer shape judgment performed by the shape/in-plane distribution recognition unit 11 will be described in detail with reference to FIG. 7. Here, profiles 72, 74, 76 of a brightness signal obtained by imaging of the image processing unit 8b from the top of the ribs correspond respectively to a shape 71 of a normal phosphor layer, a shape 73 of a phosphor layer in which the amount of phosphor is slightly small, and a shape 75 of a phosphor layer that is shifted to the right side. For the profiles 72, 74, 76 of the brightness signal, the profile width p2w at the time of brightness p2 having 70% of a peak brightness p1, and the amount of deviation “off” from a peak position, are calculated as brightness profile parameters by the shape/in-plane distribution recognition unit 11. The shape/in-plane distribution recognition unit 11 can acquire an actual shape of the phosphor layer from each of the calculated parameters p2w and off with reference to a shape/brightness model 12 that is predetermined data of the correlation between a phosphor layer shape and a brightness profile.

This makes it possible for the shape/in-plane distribution recognition unit 11 to detect a slight change in phosphor shape, which is not judged to be a defect, and to minutely recognize process fluctuations in the phosphor painting process.

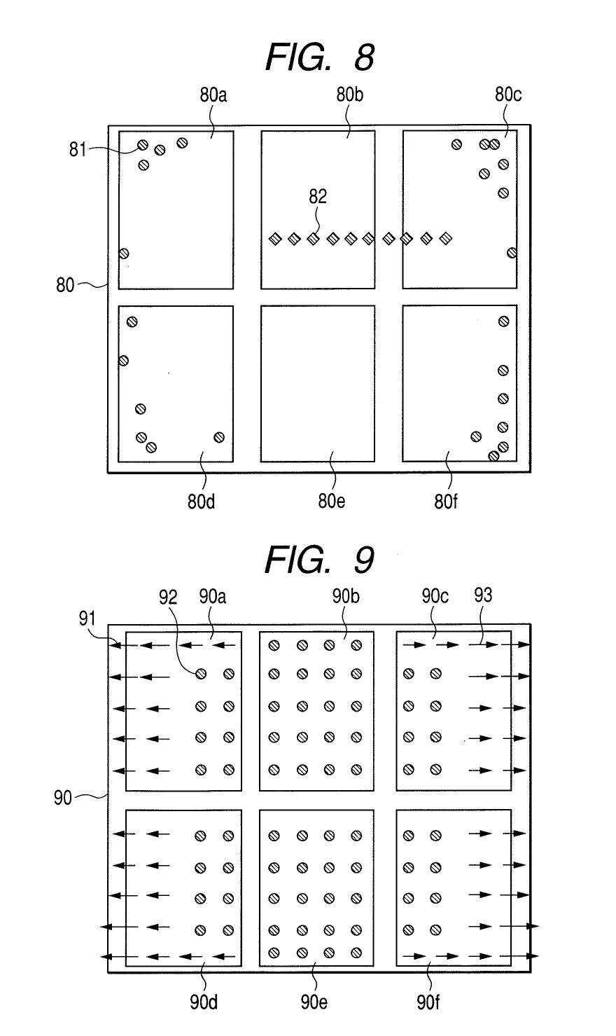

Next, processing performed by the shape/in-plane distribution recognition unit 11, and processing performed by the state judgment unit 15, will be described with reference to FIG. 8. As a result of the above-described processing, a position, a mode, and the size, of a defect on a target substrate to be inspected are known. Accordingly, the shape/in-plane distribution recognition unit 11 generates a defect distribution map 80 in which, for example, a phosphor overextension defect is indicated with a circle mark 81, and a mixed color defect is indicated with a rhombus mark 82. The generated defect distribution map 80 is transmitted to the state judgment unit 15 where state judgments are made. For example, on the basis of an occurrence position, a judgment is made as to whether each defect has occurred in the center or the periphery; and on the basis of a distribution shape, a judgment is made as to whether each defect has occurred circularly, linearly, or randomly. In addition, defect information is recorded for each of panels to be chamfered 80a through 80f.

By generating such a defect distribution map, the shape/in-plane distribution recognition unit 11 can quickly recognize the tendency of process fluctuations in the phosphor painting process.

Next, FIG. 9 is a diagram illustrating another processing example. The shape/in-plane distribution recognition unit 11 generates a deviation amount map 90 showing the geometrical displacement distribution. In the deviation amount map 90, the amount of deviation “off” of a peak position of the phosphor from the center as shown in FIG. 7 is displayed at intervals shown in FIG. 9. The amount of deviation and a direction thereof are indicated with arrows 91, 93. If there is no deviation, a circle mark 92 is given. The state judgment unit 15 makes state judgments. For example, a judgment is made as to whether a position at which the amount of deviation is large is the center or the periphery; and a judgment is made as to whether a deviation direction is constant or random. In addition, the deviation amount distribution is recorded for each of panels to be chamfered 90a through 90f.

By generating such a deviation amount map, it is possible for the shape/in-plane distribution recognition unit 11 to quickly recognize the tendency of the amount of deviation in the phosphor painting process.

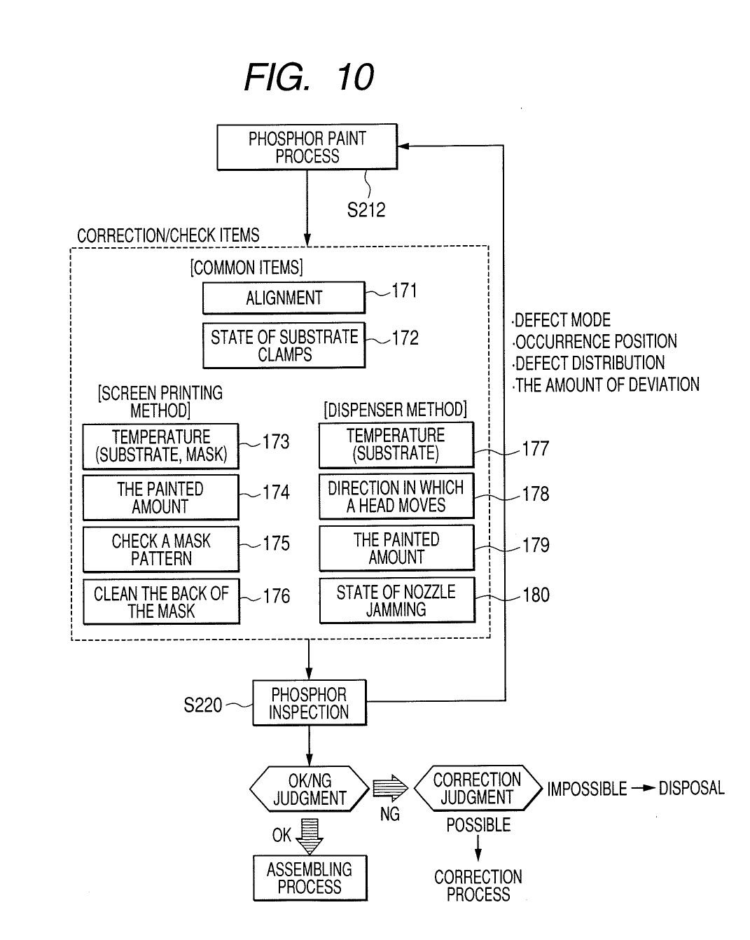

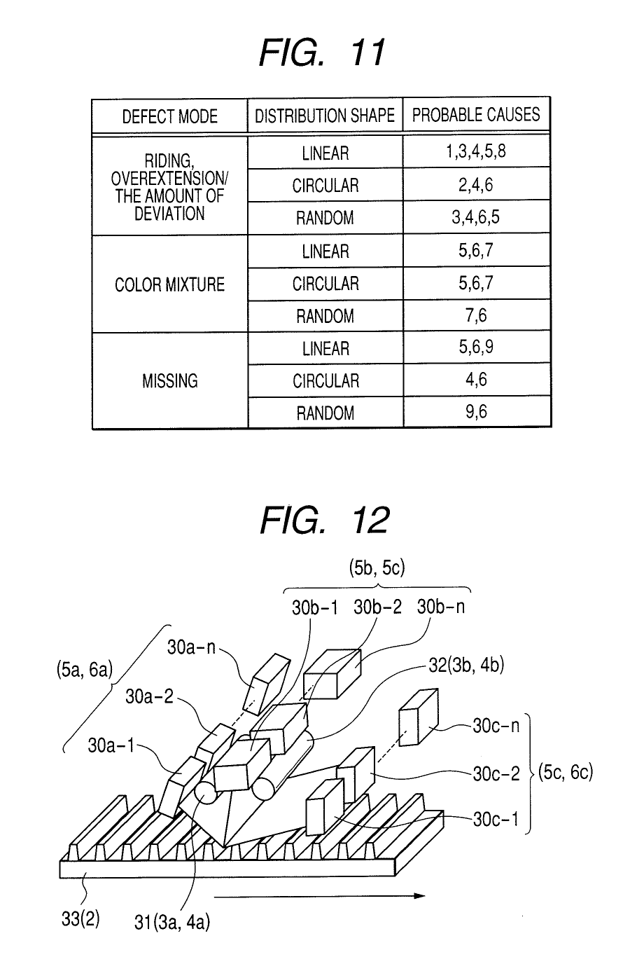

Next, an example of how to control a manufacturing process based on a manufacturing method according to the first embodiment will be described with reference to FIGS. 10 and 11. As a result of the above-described phosphor inspection S220, the manufacturing equipment 17 (phosphor painting apparatus comprises phosphor printing/calcination apparatus, etc.), which is in a state of the phosphor painting process S212 that is a step of manufacturing a phosphor layer, can recognize a position, a shape, the area (size), a defect mode, the defect distribution, and the deviation amount, of each phosphor defect. Therefore, by use of the whole or part of information about these defects, parameters of the manufacturing equipment in the phosphor painting process, which is a phosphor-layer manufacturing process, are checked and corrected. To be more specific, the above-described parameters constitute a parameter group shown in correction/check items shown in FIG. 10. As the correction/check items, for a method common to the screen printing method and dispenser method, there are alignment 171 and substrate clamp state 172. Also, as the correction/check items, for the screen printing method, there are temperature 173 (substrate, mask), applied amount 174, mask pattern confirmation 175, mask back plate cleaning 176, etc. As the correction/check items, for the dispenser method, there are temperature (substrate) 177, head running direction 178, applied amount 179, nozzle jamming state 180, etc. For example, each corresponding parameter item is checked and adjusted according to a defect/probable cause correspondence table (table including defect mode, distribution state, probable cause) shown in FIG. 11. Numbers indicated as probable causes in FIG. 11 are equivalent to the following adjustment items: Numbers indicated as probable causes in FIG. 11 are equivalent to the following adjustment items: 1, alignment (X-Y); 2, alignment (rotation); 3, clamps of a substrate; 4, thermal gradient; 5, the painted amount; 6, a mask pattern; 7, stains on the back of a mask; 8, an error of a direction in which a head moves; and 9, nozzle jamming. If the information about the defects and the information about the adjustment items are fed back to the phosphor painting process S212, it is possible to decrease the fluctuations in process state in the phosphor manufacturing process, and to manufacture the phosphor in a stable state.

Thus, according to the manufacturing method according to the first embodiment, from a phosphor application state and a shape of the phosphor layer in the phosphor formation process included in the PDP manufacturing process, it is possible to minutely and correctly recognize a process state in the phosphor painting process. Further, by quickly feeding back the process state to the phosphor painting process, it is possible to control the manufacturing equipment in the phosphor painting process. This produces extremely large effects of improving yields, improving the processes, and preventing a failure from occurring. In addition, as a result of the above-described phosphor inspection S220, the defect mode is known. Therefore, a judgment as to whether or not a defect can be corrected is also facilitated.

FIG. 12 is a perspective view illustrating a configuration of an inspection apparatus according to the first embodiment. The inspection apparatus is so configured that a target substrate 33 (2) to be inspected is irradiated with ultraviolet light by use of ultraviolet lamps 31 (3a, 4a), 32 (3b, 4b), each of which is capable of irradiating the target substrate 33 (2) with ultraviolet light from the sufficiently long distance. Detection means for detecting a light beam emitted by the phosphor divides a detection range on the basis of the resolution of a detection element and the length per element in response to each detection direction, and then places detection means 30a-1 through 30a-n (5a, 6a), 30b-1 through 30b-n (5b, 6b), 30c-1 through 30c-n (5c, 6c). A color line sensor is used as the detection element. An image is detected in synchronization with scanning of the substrate 33.

The above-described configuration makes it possible to carry out inspection at high speed even in the case of a large substrate, and to perform inspection in manufacturing tact. As a result, it is possible to realize an inline inspection apparatus.

Incidentally, the ultraviolet light can be produced by a low-pressure mercury lamp (having wavelengths of 184 nm, 254 nm). In addition, the ultraviolet light can also be produced, for example, by linearly scanning an ultraviolet laser beam having a wavelength of 400 nm or less. A KrF laser (248 nm), a KrCl laser (222 nm), an ArF laser (193 nm), and the like, can be used as a laser light source.

### Second Embodiment

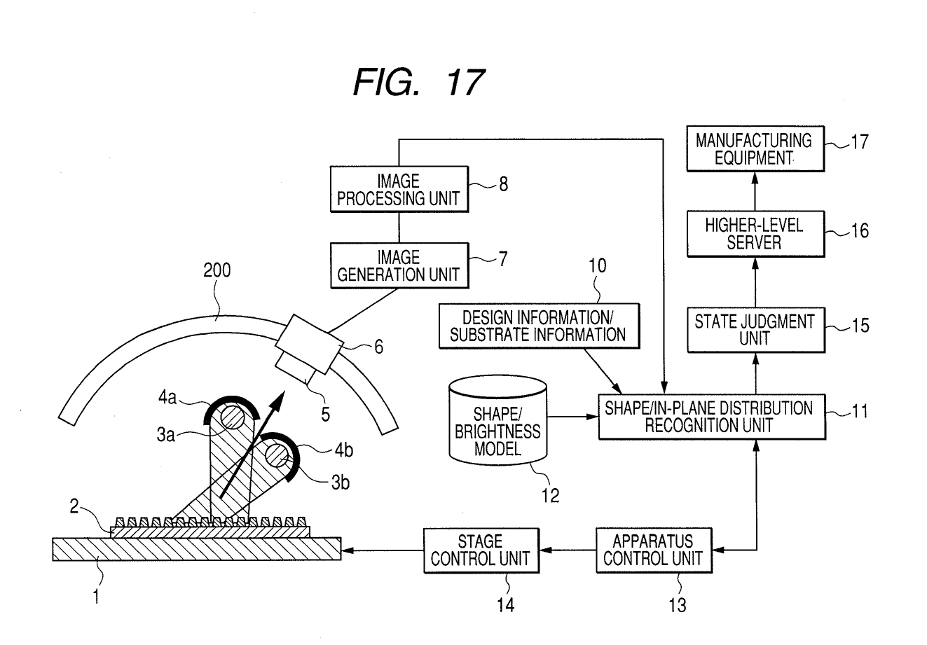

FIG. 17 is a diagram illustrating an image processing unit according to a second embodiment of the present invention. In the first embodiment shown in FIG. 1, an image is detected from three directions by use of three cameras. On the other hand, in the second embodiment, an image is detected by one camera with a direction of the camera being changed. Because the other parts of the configuration are similar to those shown in FIG. 1, the description thereof will be omitted. As is the case with FIG. 1, ultraviolet light is irradiated on the back plate 2 by ultraviolet sources 3a, 3b and reflecting plates 4a, 4b. The phosphor layer formed in the ribs on the back plate 2 is excited by the ultraviolet light. Light beams emitted from the excited phosphor are condensed through a lens 5 whose angle is set at a specified value with respect to a substrate 2. The condensed light beam is detected by a photodetector 6. An image generation unit 7 generates a two-dimensional image from the detected signal, and then transmits the two-dimensional image to an image procession unit 8. The lens 5 and the photodetector 6 are located on a rail 200 that is capable of arbitrarily changing a detection angle. By changing the detection angle, it is possible to acquire the same image as that detected by a plurality of detectors.

According to the second embodiment, the lens 5 and the photodetector 6 can be configured with one camera. This makes it possible to simplify the configuration of the inspection apparatus, and to reduce costs thereof. Moreover, if not only the image acquired in this embodiment, but also information about defects and adjustment, which has been acquired in a manner similar to that of the first embodiment, are fed back to the phosphor painting process S212, it is possible to decrease fluctuations in process state in the phosphor manufacturing process, and to manufacture the phosphor in a stable state.

### Third Embodiment

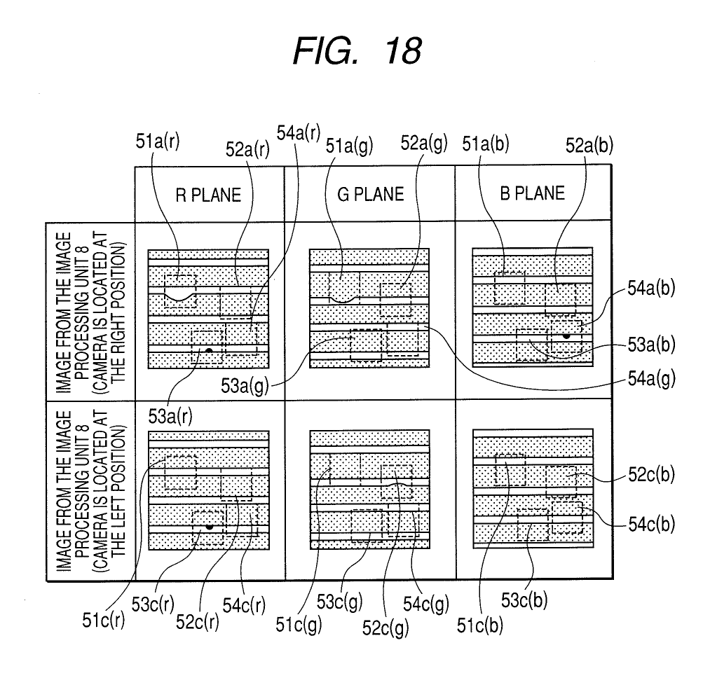

Next, FIG. 18 is a diagram illustrating a third embodiment of a defect mode judgment made by the shape/in-plane distribution tracking unit 11. FIG. 18 illustrates an example that uses an image detected from two directions. To be more specific, the image in this example is acquired by omitting the central part, which is obtained from the image processing unit 8b, from the image detected from three directions as shown in FIG. 5. As shown in the third embodiment, even if there is no detected image in the central part, it is possible to identify a defect mode (R overextension defect 51 is determined based on the defect area 51a (r) and defect area 51a (g); phosphor missing defect 52 on the G rib wall is determined based on the defect area 52c (g); defect due to foreign particle 53 in R rib is determined based on the defect area 53a (r) and defect area 53c (r); and defect due to color mixture 54 in B rib is determined based on the defect area 54a (r) and defect area 54a (b)) as shown in FIG. 6 in a manner similar to that of the detection from three directions so long as there is no undetectable area caused by blind spots of ribs.

Because a detected image detected from two directions is used, quicker processing becomes possible in comparison with the detection from three directions. Moreover, as is the case with the first embodiment, if information about defects and adjustment, which has been acquired in this embodiment, is fed back to the phosphor painting process S212, it is possible to decrease fluctuations in process state in the phosphor manufacturing process, and to manufacture the phosphor in a stable state.

What is claimed is:

1. A method for manufacturing a plasma display, the method comprising:
a phosphor painting process for painting a phosphor layer in ribs formed on a back plate of the plasma display by using a phosphor painting apparatus; and
a phosphor inspection process that includes the steps of:
irradiating the phosphor layer with ultraviolet light to cause the phosphor layer to emit a light beam, the phosphor layer being painted in the ribs;
preparing an imaging system so that the imaging system images the emitted light beam to acquire an image;
separating the acquired image into RGB planes;
inspecting a defect of the phosphor layer painted in the ribs; and
a process for feeding back information on the defect to the phosphor painting process so that manufacturing equipment is controlled in the phosphor painting process.

2. A method for manufacturing a plasma display, the method comprising:
a phosphor painting process for painting phosphor layer in ribs formed on a back plate of the plasma display by using a phosphor painting apparatus; and
a phosphor inspection process that includes the steps of:
irradiating the phosphor layer with ultraviolet light to cause the phosphor layer to emit a light beam, the phosphor layer being painted in the ribs;
preparing an imaging system so that the imaging system images the emitted light beam from a specified direction to acquire an image;
separating the acquired image into RGB planes;
obtaining each difference area between the RGB planes
inspecting a defect of the phosphor layer painted in the ribs based on the obtained difference areas; and
obtaining defect information on the position, the shape and the area (size) of the defect; and
a process for feeding back the defect information on the position, the shape and the area (size) of the defect to the phosphor painting process so that the manufacturing equipment is controlled in the phosphor painting process.

3. A method for manufacturing a plasma display, the method comprising:
a phosphor painting process for painting phosphor layer in ribs formed on a back plate of the plasma display by using a phosphor painting apparatus; and
a phosphor inspection process that includes the steps of:
irradiating the phosphor layer with ultraviolet light to cause the phosphor layer to emit a light beam, the phosphor layer being painted in the ribs;
preparing an imaging system so that the imaging system images the emitted light beam from a plurality of directions to acquire a plurality of images;
separating each of the acquired images into RGB planes;
comparing the RGB planes with each other to judge a defect mode of the phosphor layer painted in the ribs; and
obtaining information on a defect of the phosphor layer, the information including the defect mode; and
a process for feeding back the defect mode to the phosphor painting process so that the manufacturing equipment is controlled in the phosphor painting process.

4. A method for manufacturing a plasma display, the method comprising:
a phosphor painting process for painting phosphor layer in ribs formed on a back plate of the plasma display by using a phosphor painting apparatus; and
a phosphor inspection process that includes the steps of:
irradiating the phosphor layer with ultraviolet light to cause the phosphor layer to emit a light beam, the phosphor layer being painted in the ribs;
preparing an imaging system so that the imaging system images the emitted light beam to acquire information on brightness;
comparing the brightness information with correlation between a shape model of the phosphor layer and brightness signal information that have been obtained in advance; and
obtaining a painted state of the phosphor layer applied in the ribs; and
a process for feeding back the painted state of the phosphor layer, which has been obtained in the phosphor inspection process, to the phosphor painting process so that the manufacturing equipment is controlled in the phosphor painting process.

5. An apparatus for inspecting a phosphor layer that is formed on a back plate of a plasma display, the apparatus comprising:
a holding unit for holding the back plate;
a driving unit for causing the holding unit to travel;
an ultraviolet-light irradiation optical system for irradiating the phosphor layer with ultraviolet light;
an imaging unit for imaging light from which the phosphor layer emits in response to the irradiation with the ultraviolet light so as to acquire an image, the irradiation having been performed by the ultraviolet-light irradiation optical system; and
a defect judgment unit for separating, into RGB planes, the image that has been acquired by the imaging unit, inspecting a defect of the phosphor layer painted in the ribs based on each of the RGB planes, and obtaining information on the defect of the phosphor layer.

6. An apparatus for inspecting a phosphor layer that is formed on a back plate of a plasma display, the apparatus comprising:
a holding unit for holding the back plate;
a driving unit for causing the holding unit to travel;
an ultraviolet-light irradiation optical system for irradiating the phosphor layer with ultraviolet light;
an imaging unit for imaging, from a specified direction, light from which the phosphor layer emits in response to the irradiation with the ultraviolet light so as to acquire an image, the irradiation having been performed by the ultraviolet-light irradiation optical system; and
an image processing unit for separating, into RGB planes, the image that has been acquired by the imaging unit, obtaining each different area between the RGB planes inspecting a defect of the phosphor layer painted in the ribs based on each of the obtained different areas, and obtaining information on the defect of the phosphor layer, the information including the position, the shape and the size of the defect.

7. An apparatus for inspecting a phosphor layer that is formed on a back plate of a plasma display, the apparatus comprising:
a holding unit for holding the back plate;
a driving unit for causing the holding unit to travel;
an ultraviolet-light irradiation optical system for irradiating the phosphor layer with ultraviolet light;
an imaging unit for imaging, from a plurality of directions, light from which the phosphor layer emits in response to the irradiation with the ultraviolet light so as to acquire a plurality of images, the irradiation having been performed by the ultraviolet-light irradiation optical system; and
a defect calculation unit for separating, into RGB planes, the plurality of images that have been acquired by the imaging unit, comparing the RGB planes with each other to inspect a defect mode of the phosphor layer painted in the ribs, and obtaining information on a defect of the phosphor layer, the information including the defect mode.

8. An apparatus for inspecting a phosphor layer that is formed on a back plate of a plasma display, the apparatus comprising:
a holding unit for holding the back plate;
a driving unit for causing the holding unit to travel;
an ultraviolet-light irradiation optical system for irradiating the phosphor layer with ultraviolet light;
an imaging unit for imaging light from which the phosphor layer emits in response to the irradiation with the ultraviolet light so as to obtain information on a brightness signal, the irradiation having been performed by the ultraviolet-light irradiation optical system; and
an shape/in-plane distribution recognition unit for comparing the information on the brightness signal with correlation between a shape model of the phosphor layer and brightness signal information that have been obtained in advance to obtain a painted state of the phosphor layer painted in the ribs.
